(19) United States
(12) Patent Application Publication
(10) Pub. No.: US 2008/0017238 A1
(43) Pub. Date: Jan. 24, 2008

(54) Thermoelectric device

(75) Inventors: Dong Fei, Peoria, IL (US); Mahmoud A. Taher, Peoria, IL (US); Bao Feng, Dunlap, IL (US); Leonard George Wheat, Manito, IL (US); Beth Ann Howe, Lewistown, IL (US)

Correspondence Address: CATERPILLAR/FINNEGAN, HENDERSON, L.L.P., 901 New York Avenue, NW, WASHINGTON, DC, 20001-4413, US

(73) Assignee: Caterpillar Inc.

(21) Appl. No.: 11/490,135

(22) Filed: Jul. 21, 2006

(51) Int. Cl. H01L 35/28

(52) U.S. Cl. 136/224

(57) ABSTRACT

A thermoelectric device includes a plurality of n-type thermoelectric elements and a plurality of p-type thermoelectric elements. These thermoelectric elements each have multiple end surfaces that are substantially parallel to each other, and include terminals attached to the end surfaces. The thermoelectric elements also include a support structure with an external surface covered by multiple layers of a thermoelectric material and a flexible substrate. The thermoelectric device also includes a plurality of conductive members which electrically interconnect the thermoelectric elements.

### U.S.-GOVERNMENT RIGHTS

This invention was made with government support under the terms of Contract No. ZCL-4-32060-04 awarded by the Department of Energy. The government may have certain rights in this invention.

### TECHNICAL FIELD

The present disclosure relates generally to a thermoelectric device, and more particularly, to a thermoelectric device with cylindrical thermoelectric elements.

### BACKGROUND

Internal combustion engines generate energy by combustion of fossil fuels. Some of this energy is harnessed to power machines such as trucks, trains, and heavy equipment, while some of the energy is released as thermal energy. A small amount of the thermal energy may be used for various machine operations, but much of the thermal energy is wasted as it is released in exhaust gases and in the engine cooling system. To improve overall machine efficiency, it would be useful to convert wasted thermal energy into a useful form.

Thermoelectric power units can be used to convert the wasted thermal energy into electrical energy, which may be used to power a variety of different machine operations. Thermoelectric power units can include a variety of different thermoelectric devices, and operate by converting a temperature difference across the device into electrical energy. The temperature difference across the thermoelectric device can be maintained by exposing the device to the wasted thermal energy at one end and a cooling source, like atmospheric cooling, or a heat exchanger of the machine at the other end. The efficiency and total power output of the thermoelectric power unit may depend on a number of factors including, for example, the type of thermoelectric materials used and the maintained temperature difference across the material. Conversion efficiency is a measure of the effectiveness of a thermoelectric device in converting thermal energy to electrical energy. Commercially available thermoelectric devices based on traditional bulk thermoelectric materials have poor conversion efficiencies. Recent advances in materials technologies have shown that nano-structured thin film materials can be engineered to have superior thermoelectric properties. However, low cost and robust methods to process these materials and assemble them into thermoelectric devices are needed before these nano-structured thin film thermoelectric materials can be widely used for commercial applications.

One thermoelectric power production device is described in U.S. Patent Publication 2005/0139250 A1 issued to DeSteese et al. (hereinafter the '250 publication). The '250 publication discloses thin film thermoelectric devices that operate at 5 to 20° C. temperature differentials to produce power between 1 μW and 1 W. The thermoelectric devices of the '250 publication are configured to operate under a small temperature differential to produce low power.

While the thermoelectric device of the '250 publication may be effective for the constraints it is designed to operate under, it may have several drawbacks for commercial application in a machine environment. For example, the device of the '250 publication may require a substantial amount of processing, for instance multiple masking and deposition steps, which can make fabrication expensive and complex. In addition, the device of the '250 publication may not generate enough power to make it economical to be used in a machine environment.

The present disclosure is directed at overcoming one or more of the shortcomings of the prior art thermoelectric systems.

### SUMMARY OF THE INVENTION

In one aspect, the present disclosure is directed to a thermoelectric device which includes a plurality of n-type thermoelectric elements and a plurality of p-type thermoelectric elements. The thermoelectric elements each have multiple end surfaces that are substantially parallel to each other, and include terminals attached to the end surfaces. The thermoelectric elements also include a support structure with an external surface covered by multiple layers of a thermoelectric material and a flexible substrate. The thermoelectric device also includes a plurality of conductive members which electrically interconnect the thermoelectric elements.

In another aspect, the present disclosure is directed to a thermoelectric device which include a plurality of generally cylindrical n-type thermoelectric elements with substantially parallel end surfaces, including a support structure, and a thermoelectric film. The thermoelectric film includes a flexible substrate on which a n-type thermoelectric material is deposited on at least one surface. The thermoelectric device also includes a plurality of generally cylindrical p-type thermoelectric elements with substantially parallel end surfaces, including a support structure, and a thermoelectric film. The thermoelectric film includes a flexible substrate on which a p-type thermoelectric material is deposited on at least one surface. Terminals are also attached to the end surfaces.

The present disclosure also discloses a method of making a thermoelectric device. The method includes depositing thermoelectric material on a flexible substrate to form a thermoelectric film, winding the thermoelectric film around a support structure multiple complete turns to form a thermoelectric element, attaching terminals to parallel end surfaces of the thermoelectric element, and interconnecting the thermoelectric elements serially with conductive tabs.

### BRIEF DESCRIPTION OF THE DRAWINGS

FIG. 1 is a diagrammatic illustration of an exemplary disclosed machine;

FIG. 2 is a diagrammatic illustration of an application of a thermoelectric module in the machine of FIG. 1;

FIG. 3 is a diagrammatic illustration of an embodiment of a thermoelectric device in the thermoelectric module of FIG. 2;

FIG. 4 is a cross-sectional view of the thermoelectric device along plane 4-4 of FIG. 3;

FIG. 5a-5d is a diagrammatic illustration of the method of making a thermoelectric element;

FIG. 6a illustrates a cross-sectional view of one embodiment of the thermoelectric element along plane 6a-6a in FIG. 5d; and

FIG. 6b illustrates a cross-sectional view of another embodiment of the thermoelectric element.

### DETAILED DESCRIPTION

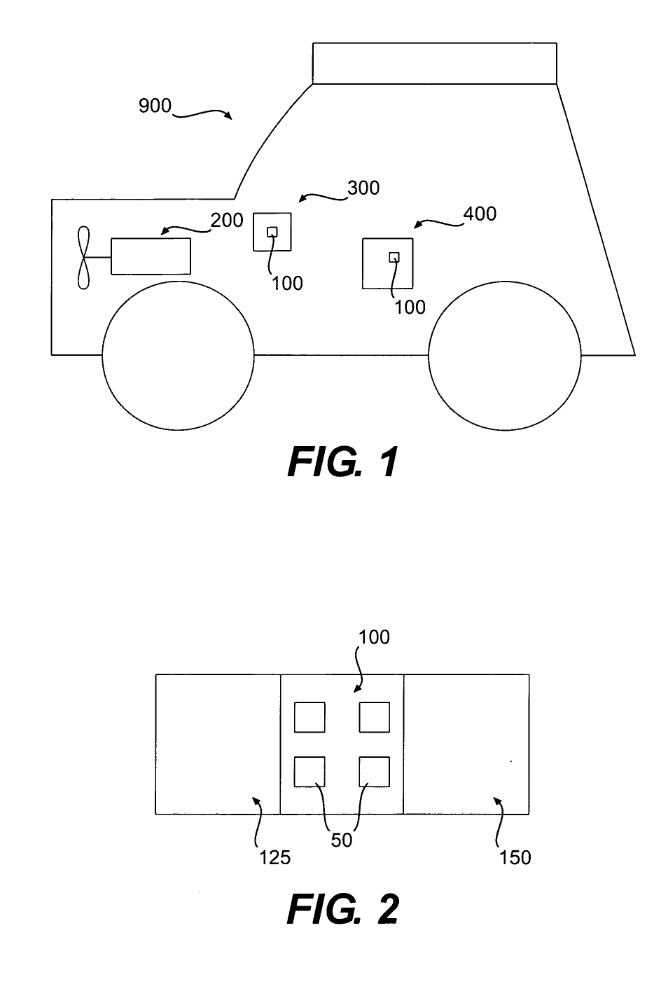

FIG. 1 illustrates an exemplary machine 900 having multiple systems and components that cooperate to accomplish a task. Machine 900 may embody a fixed or mobile machine that performs some type of operation associated with an industry such as mining, construction, farming, transportation, or any other industry known in the art. For example, machine 900 may be a transportation machine such as a car, train, or an airplane, an earth moving machine such as an excavator, a dozer, a loader, a backhoe, a motor grader, a dump truck, or any other machine. Machine 900 may include a power source 200, an HVAC system 300, an exhaust system 400, and many other systems which are not shown. The exhaust system 400, the HVAC system 300, and other systems of machine 900 may include a thermoelectric module 100.

FIG. 2 illustrates an application of a thermoelectric module 100. The thermoelectric module 100 may include several thermoelectric devices 50. The thermoelectric module 100 used in an exhaust system 400 uses the temperature difference between a hot region 125 and a cold region 150 to generate electric power within thermoelectric module 100. The hot region 125 can be any hot source, including hot exhaust gases. The cold region 150 can be any cold source, including circulating cooling liquids and atmospheric air. The power generated by the thermoelectric device 50 may be used to help drive other systems of the machine.

The thermoelectric module 100 used within an HVAC system 300 acts as a heat pump. In such an application, electric power is supplied to the thermoelectric module 100. The current drives a transfer of heat from one end of the thermoelectric module 100 to the other, creating a hot region 125 and a cold region 150. The cold region 150 may be used to cool, or the hot region 125 may be used to warm other parts or systems of the machine 900. For example, the cold region 150 can be used to cool air in a HVAC system, and the hot region 125 can be used to warm oil or fuel. The thermoelectric module 100 may comprise several thermoelectric devices 50.

Although the thermoelectric module 100 is described for application in an exhaust system 400 and an HVAC system 300 of the machine, these descriptions are illustrative only. It is understood that the thermoelectric module 100 can be used anywhere where heat energy is to be converted to electrical energy or where electrical energy is to be used to create a temperature differential between two regions.

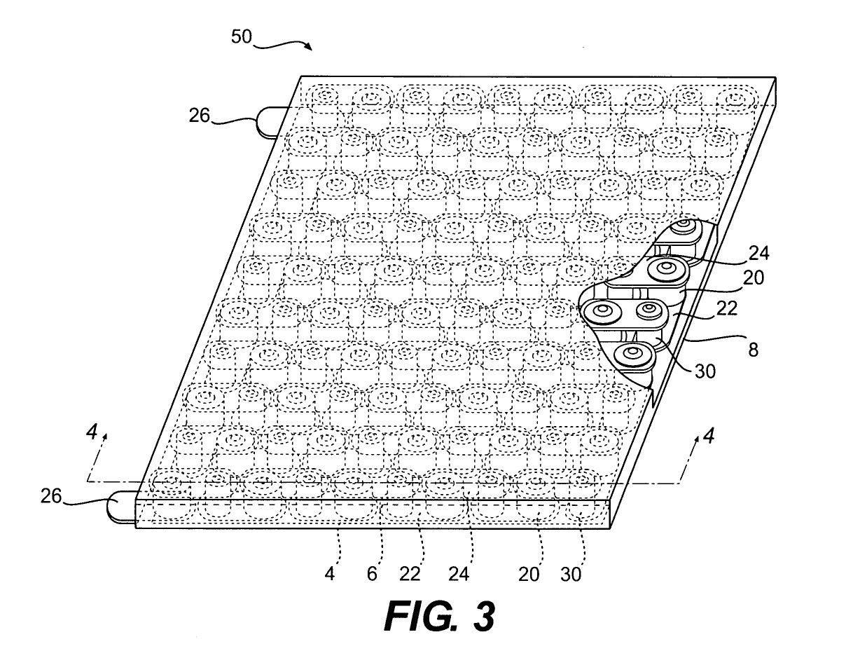

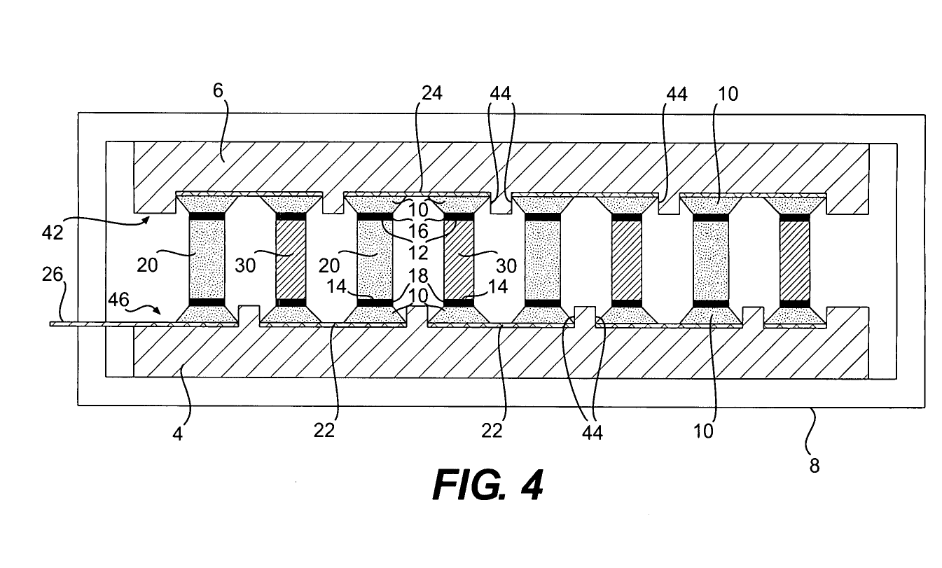

FIG. 3 is an diagrammatic illustration of a thermoelectric device 50 that may make up the thermoelectric module 100 in FIG. 2. FIG. 4 is a cross-sectional view of the thermoelectric device along plane 4-4 of FIG. 3. In the description that follows, reference is made to both FIGS. 3 and 4. The thermoelectric device 50 may be made up of a plurality of n-type thermoelectric elements 30 and p-type thermoelectric elements 20. Both n-type and p-type thermoelectric elements 30, may each have a generally cylindrical surface and opposing substantially parallel end surfaces—top end surface 12, and bottom end surface 14. A top terminal 16 may be attached to the top end surfaces 12 of the n-type and p-type thermoelectric elements 30, 20. A bottom terminal 18 may also be attached to the bottom end surfaces of the n-type and p-type thermoelectric elements 30, 20. The top terminals 16 of the n-type and p-type thermoelectric elements 30, 20 may be connected to a top cover electrically conductive tab 24 through an electrically conductive adhesive 10. The bottom terminal 18 of the n-type and p-type thermoelectric elements may also be connected to a bottom cover electrically conductive tab 22 also through an electrically conductive adhesive 10. Top cover electrically conductive tabs 24 may be attached to the bottom of cavities 44 on an inside surface 42 of a top cover plate 6, and the bottom cover electrically conductive tabs 22 may be attached to the bottom of cavities 44 on an inside surface 46 of a bottom cover plate 4. The terminals 16, 18 may be made of any electrically conductive material such as chromium, molybdenum, or aluminum.

The top and bottom cover tabs 24, 22 may be attached to the bottom of the cavities 44 using an adhesive (not shown), or it may be coated to the bottom surface of the cavity 44. Any electrically conductive adhesive 10 known in the art may be used to connect the thermoelectric elements 20, 30 to the top and bottom cover tabs 24, 22 and any common adhesive known in the art can be used to attach the tabs 22, 24 to the top and bottom cover plates 6, 4. For example, phosphate binders, metal filled epoxies, metal pastes, or high temperature solders or any other adhesive which is electrically conductive may be used as the electrically conductive adhesive 10, and any adhesive epoxies or glue may be used to attach the tabs 22, 24 to the bottom of the cavities 44. Any electrically conductive material, such as nickel, copper, or aluminum, can be used as the tabs 22, 24. If a coating process is used to form the tabs 22, 24 at the bottom of the cavities 44, any coating technique known in the art, such as plating, sputtering, etc., may be used.

The top and bottom cover tabs 24, 22 are used to electrically interconnect the n-type and p-type thermoelectric elements 30, 20 serially. A bottom cover tab 22 may electrically connect the bottom terminal 18 of one of the n-type thermoelectric elements 30 to the bottom terminal 18 of an adjacent p-type thermoelectric element 20. A top cover electrically conductive tab 24 may electrically connect the top terminal 16 of the same p-type thermoelectric element 20 to the top terminal 16 of a different adjacent n-type thermoelectric element 30. The bottom terminal 18 of this n-type thermoelectric element 30 may then be connected to the bottom terminal 18 of a different adjacent p-type thermoelectric element 20. This interconnection pattern may be repeated until all the n-type and p-type thermoelectric elements 30, 20 are connected together serially. At least two electrically conductive leads 26 may electrically connect to the interconnected thermoelectric elements, and extent outside the housing. Other interconnection schemes may also be used to interconnect the n-type and p-type thermoelectric elements 30, 20.

A housing 8 may enclose the top and bottom cover plates 6, 4, the plurality of n-type and p-type thermoelectric elements 30, 20, and the top and bottom terminals 16, 18 to protect it from pollutants, and increase the structural robustness of the device. In some applications, the housing 8 may also be used to seal the enclosed elements in a vacuum. Although the housing 8 is shown as substantially enclosing the other components of the thermoelectric device 50, the housing 8 can be of any form or, in some applications, be eliminated.

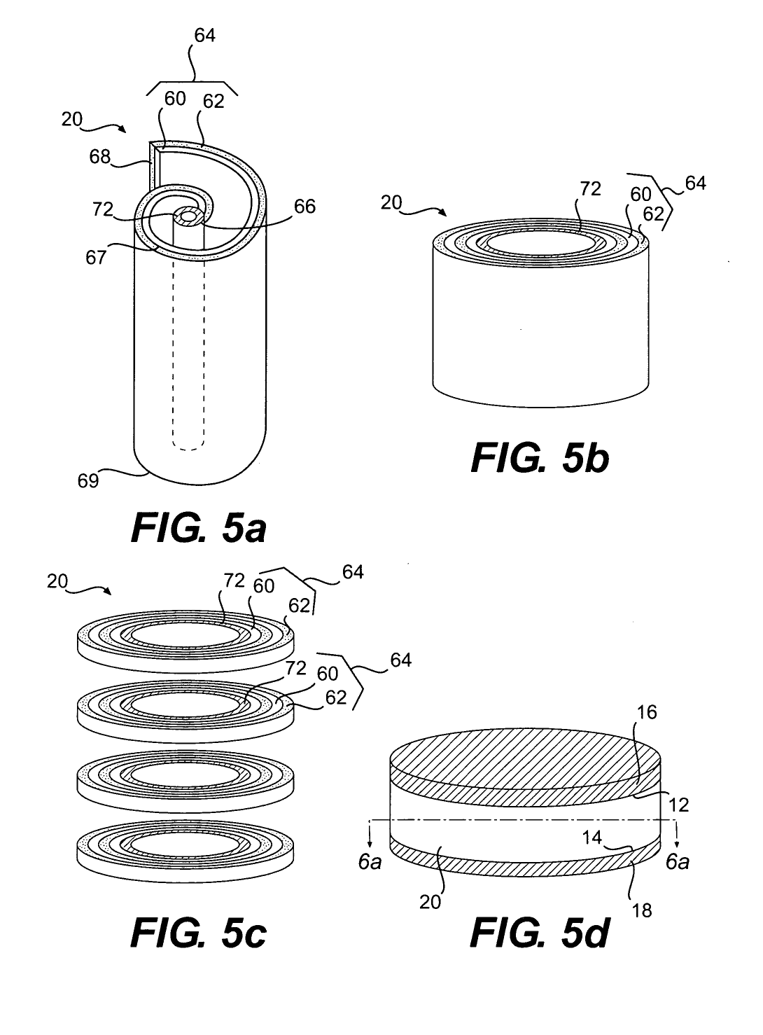

FIGS. 5a, 5b, 5c, and 5d, illustrate the method of making a p-type thermoelectric element 20. Thermoelectric material 62 of p-type, is deposited on low-cost high temperature flexible substrate 60 with low thermal and electrical conductivities. Such a substrate could include any polyamide, Kapton® tape or any other suitable flexible substrate. Any deposition technique, for example sputtering, can be used to deposit the thermoelectric material 62 on the substrate 60. Any thermoelectric material can be deposited on the flexible substrate 60 to act either as a p-type or n-type thermoelectric element. For example, different stochiometries of boron carbine, silicon carbide, silicon germanium, bismuth telluride, germanium telluride, or any other thermoelectric material known in the art may be used as the thermoelectric material 62. These materials can also have any structure including zero-dimensional quantum dots, one-dimensional nano wires, two-dimensional quantum well and superlattice thermoelectric structures. The thermoelectric material 62 deposited on the flexible substrate 60 together constitute the thermoelectric film 64. The thermoelectric film includes two pairs of opposite edges—a first edge 66, a second edge 68, a third edge 67 and a fourth edge 69. The p-type thermoelectric element 20 is formed by winding the thermoelectric film 64 around a support structure which may have low thermal and electrical conductivity. The support structure may have any form. For example, the support structure have the form of a hollow tube 72. Hereinafter, the support structure will be described as a hollow tube 72. Such a hollow tube 72 may be formed of, for example, alumina or other suitable materials.

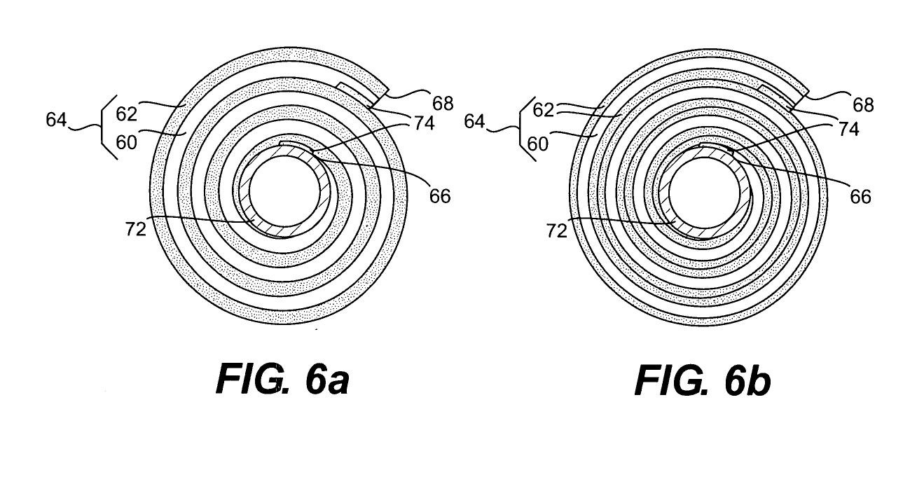

As shown in FIG. 5a, the first edge 66 of the thermoelectric film 64 may be attached, using an attachment medium 74 (see FIG. 6a), to the external cylindrical surface of the hollow tube 72 in the longitudinal direction. The thermoelectric film 64 may then be wound around the hollow tube 72 multiple complete turns so that the thermoelectric film 64 is tightly wrapped around the hollow tube 72. [The second edge 68 of the thermoelectric film 64 may then be attached to the wound surface of the thermoelectric film 64 with the attachment medium 74 (see FIG. 6a).] Any adhesive known in the art, such as epoxy, glue, sticky disk, sticky tape or any other sticky substance can be used as the attachment medium 74.

FIG. 5b is an illustration of the p-type thermoelectric element 20 after completion of the winding and attachment process described above. The thermoelectric element 20 may then be cut into multiple pieces of desired lengths. These pieces could be of the same or different lengths.

FIG. 5c is an illustration of the thermoelectric elements that have been cut to a desired length. Any cutting process known in the art, such as water jet cutting, laser cutting, diamond saw cutting or any other cutting technique can be used. An alternative method of forming the elements illustrated in FIG. 5c is to cut the thermoelectric film 64 into strips of a desired width, and then wind the strips on hollow tubes 72 which have been pre-cut to the desired width. A flexible substrate 60 of the desired width can also be coated with the thermoelectric material 62 before being wound on hollow tubes 72 of the desired width.

The top and bottom terminals 16, 18 may be formed by coating the top and bottom end surfaces 12, 14 of the p-type thermoelectric element 20. FIG. 5d illustrates the p-type thermoelectric element 20 after coating the top and bottom terminals 16, 18. In some applications, the third and fourth edges 67, 69 (see FIG. 5a) of the thermoelectric film 64 may be coated with the material of the terminal, before it is wound around the hollow tube 72 to form the top and bottom terminals 16, 18. Any electrically conductive material, such as chromium, molybdenum, or aluminum, may be used as the top and bottom terminals 16, 18, and any coating process known in the art can be used for forming the terminals 16, 18.

FIG. 6a is a cross-sectional illustration of the p-type thermoelectric element 20 along plane 6a-6a of FIG. 5d. FIG. 6a shows the hollow tube 72 with its external cylindrical surface covered by multiple turns of the thermoelectric film 64. The thermoelectric film 64 is formed by depositing the thermoelectric material 62 on only one side of the flexible substrate 60. Attachment medium 74 is used to attach the first edge 66 of thermoelectric film 64 to the hollow tube 72, and the second edge 67 to the wound cylindrical surface of the thermoelectric film 64.

In an alternative embodiment, illustrated in FIG. 6b, the thermoelectric film 64 is formed by depositing the thermoelectric material 62 on both sides of the flexible substrate 60. The thermoelectric element 20 may then be formed from the thermoelectric film 64 in the same manner as described above.

Both the n-type and the p-type thermoelectric elements 30, 20 may be formed in the same manner as described above, except that a thermoelectric material 62 of n-type is deposited on the flexible substrate 60 to form the thermoelectric film 64 of n-type. The thermoelectric film 64 of n-type may then be wound around and attached to a hollow tube 72, and its parallel end surfaces 12, 14 coated with the terminals 16, 18 as described above.

The thicknesses of the flexible substrate 60 and thermoelectric material 62 can be any value that will provide adequate structural support, without cracking when the thermoelectric film 64 is wound around the hollow tube 72. For some applications within a machine, the thickness of the flexible substrate 60 may be between approximately 7 and 30 microns, and the thickness of each deposited layer of the thermoelectric material 62 may be between approximately 2 and 10 microns. The size of each cylindrical thermoelectric element 20, 30 may be between approximately 0.5 and 1 centimeter in diameter, and approximately 2.5 and 4.5 centimeters in height. The dimensions described in this paragraph are illustrative only. It is understood that the required power, in the case of power generation application, or the required temperature in the case of heat pump applications will dictate the physical size of the cylindrical thermoelectric elements 20, 30.

Any sequence of operations may be used to assemble the thermoelectric device 50. One suitable technique to assemble the thermoelectric device 50 is described below. A conductive adhesive 10 may be placed in the cavities 44 of the bottom cover plate 4. The thermoelectric elements 20, 30 may then be placed on the conductive adhesive 10 in the cavities 44 such that the bottom end surface 14 of the thermoelectric elements 20, 30 are substantially parallel to the bottom of the cavities. The thermoelectric elements 20, 30 may also be individually attached to the bottom of the cavities 44 using conductive adhesive 10, as depicted in FIG. 4. The conductive adhesive 10 may then be cured. After curing, the assembly may be flipped and placed on the top cover plate 6 with conductive adhesive 10 placed inside its cavities 44. The whole assembly may then be cured and placed inside the housing 8. The assembly can be secured to the housing 8 by any means known in the art.

### INDUSTRIAL APPLICABILITY

The disclosed thermoelectric device 50 may be applicable to any machine including a fixed or a mobile machine that performs any type of operation. For example, the thermoelectric device 50 may be used in association with an industry such as mining, construction, farming, transportation, aerospace or any other industry known in the art. The disclosed thermoelectric device 50 with n-type and p-type thermoelectric elements 30, 20 can be used to generate power from waste heat that is a byproduct of machine operation. The power produced by the thermoelectric device 50 can be used to assist in the driving of any system of the machine, decreasing the fuel consumed by the machine, and thereby increasing its efficiency. The disclosed thermoelectric device 50 with n-type and p-type thermoelectric elements 30, 20 can also be used as a heat pump to cool or heat an object.

When the thermoelectric device 50 is used in a module used to generate power, the thermoelectric device 50 converts thermal energy from a temperature gradient between a hot region and a cold region into electrical energy utilizing the Seebeck effect. When the thermoelectric device 50 is used as a heat pump, it converts electrical energy into a temperature gradient utilizing the Peltier effect. The absence of moving parts in the thermoelectric device will make such a power production thermoelectric device or a heat pump reliable and quiet. The operation of thermoelectric device 50 with n-type and p-type thermoelectric elements 30, 20 will now be explained.

During operation of machine 100, waste heat, either in the form of hot exhaust gases or hot surfaces, produce a hot region. Thermoelectric devices 100 are arranged such that one of the cover plates 4, 6 are in thermal contact with the hot region, and the other cover plate in thermal contact with a cooler region. The cooler region can be any surface of the machine that has a temperature lower than the hot region, for instance a heat exchanger, or atmospheric air. Since the opposite end surfaces 12, 14 of the thermoelectric elements 20, 30 are in contact with opposite cover plates 4, 6, a temperature differential is created between the two junctions of the thermoelectric elements 20, 30. P-type thermoelectric elements 20 are those which are created using p-type thermoelectric materials 62 where the primary charge carriers are holes, and n-type thermoelectric elements 30 are those where the primary charge carriers are electrons. Thermoelectric materials can produce a voltage potential in the presence of a temperature gradient across the thermoelectric materials and, alternately, can produce a temperature gradient in response to an applied voltage potential. The magnitudes of the temperature gradient and the voltage may be proportionally related. When p-type and n-type thermoelectric elements 30, 20 are connected electrically in series and thermally in parallel, with one junction in the hot region and the other at the cold region, a potential difference is created due to the Seebeck effect. The potential difference generates a current when connected to an electrical load. Electrically conductive leads 26 conduct the power generated by the thermoelectric device 50 to outside the housing 8. If multiple thermoelectric devices 50 are present in thermoelectric module 100, the leads 26 of multiple thermoelectric devices 50 may be connected together, to combine the power produced by all the thermoelectric devices 50 to do useful work in the machine.

When the thermoelectric modules 100 are used as a heat pump, the electrically conductive leads 26 are used to supply power to the thermoelectric device 50 from outside the housing 8. This electric power, establishes current flow through the n-type and p-type thermoelectric elements 30, 20. When a current is passed through n-type and p-type thermoelectric elements 30, 20 that are connected to each other at two junctions, a flow of electrons and holes are established. The electrons move from the n-type to the p-type material and the holes from the p-type to the n-type material through the top and bottom cover tabs 24, 22. The charge carriers jump to a higher energy state absorbing thermal energy at the cold side and drops to a lower energy state releasing energy as heat to the hot side. This transfer of heat causes one junction to cool and the other junction to heat up. The hot end may be used to heat parts of the machine that need heating, and the cool end may be used to cool parts that need cooling.

One n-type and one p-type thermoelectric element 20, 30 constitute a thermoelectric couple. The thermoelectric device 50 can include one or more thermoelectric couples depending upon the performance requirements. The thermoelectric elements are formed by blanket deposition of the thermoelectric material 62 over a thin film substrate 60, thereby avoiding masking and deposition operations. The power produced by thermoelectric elements can be increased by increasing the cross-sectional area of the thermoelectric material 62 available for heat flow. The cross-sectional area of the thermoelectric material 62 available for heat flow corresponds to the area of the thermoelectric material 62 exposed in FIGS. 6a and 6b. Since both p-type and n-type thermoelectric elements 20, 30 are formed by wrapping the thermoelectric film 64 around a hollow tube 72 multiple turns, the cross-sectional area of the thermoelectric material 62 available for heat flow can be increased by increasing the number of turns of the thermoelectric film 64 around the hollow tube 72, without having to deposit a thicker layer of thermoelectric material 62 on the flexible substrate 60.

Low conductivity tubes are used instead of solid bars to increase the thermal resistance of the center support, and to force most of the heat to flow through the thermoelectric material. It will be apparent to those skilled in the art that various modifications and variations can be made to the disclosed thermoelectric device 50. Other embodiments will be apparent to those skilled in the art from consideration of the specification and practice of the disclosed thermoelectric device 50. It is intended that the specification and examples be considered as exemplary only, with a true scope being indicated by the following claims and their equivalents.

What is claimed is:

1. A thermoelectric device comprising;
a plurality of n-type thermoelectric elements and a plurality of p-type thermoelectric elements, at least one of the thermoelectric elements including
multiple end surfaces, the end surfaces being substantially parallel to each other, and
a support structure with an external surface covered by multiple layers of a thermoelectric material and a flexible substrate;
terminals attached to the end surfaces of the thermoelectric elements; and
a plurality of conductive members electrically interconnecting the thermoelectric elements.

2. The thermoelectric device of claim 1, wherein the plurality of conductive members include
a first conductive member electrically connecting the bottom terminal of a first n-type thermoelectric element to the bottom terminal of a first p-type thermoelectric element,
a second conductive member electrically connecting the top terminal of the first p-type thermoelectric element to the top terminal of a second n-type thermoelectric element,
a third conductive member electrically connecting the bottom terminal of the second n-type thermoelectric element to the bottom terminal of a second p-type thermoelectric element, and the thermoelectric elements further includes
a plurality of conductive leads that electrically connect to the conductive members and extend outside a housing of the thermoelectric element.

3. The thermoelectric device of claim 1, wherein the n-type and p-type thermoelectric elements are connected together electrically in series and thermally in parallel.

4. The thermoelectric device of claim 1, wherein the support structure is a hollow tube, and the multiple layers of thermoelectric material and flexible substrate alternate each other in a radial direction.

5. The thermoelectric device of claim 4, wherein the flexible substrate is made of Kapton®, the hollow tube is made of alumina.

6. The thermoelectric device of claim 4, wherein the n-type and p-type thermoelectric material include boron carbide, silicon carbide, silicon germanium, bismuth telluride, or germanium telluride.

7. The thermoelectric device of claim 1, further including,
multiple cover plates and a housing,
wherein the conductive members are attached to an inside surface of the cover plates, and the terminals are attached to the conductive members using an electrically conductive adhesive material.

8. The thermoelectric device of claim 7, wherein the cover plates have a plurality of cavities formed on an inside surface.

9. The thermoelectric device of claim 8, wherein the conductive members are attached to the cavities.

10. The thermoelectric device of claim 9, wherein the conductive members are coated on the cavities.

11. The thermoelectric device of claim 1, wherein an outer diameter of the plurality of thermoelectric elements are between approximately 0.5 and 1 centimeter, and the plurality of thermoelectric elements include a height of between approximately 2.5 and 4.5 centimeters

12. The thermoelectric device of claim 1, wherein the plurality of thermoelectric elements have a generally cylindrical shape.

13. The thermoelectric device of claim 1, wherein the thermoelectric material is deposited on the flexible substrate.

14. A thermoelectric device comprising;
a plurality of generally cylindrical n-type thermoelectric elements with substantially parallel end surfaces, including
a support structure, and
a thermoelectric film, the thermoelectric film including a flexible substrate on which a n-type thermoelectric material is deposited on at least one surface;
a plurality of generally cylindrical p-type thermoelectric elements with substantially parallel end surfaces, including
a support structure, and
a thermoelectric film, the thermoelectric film including a flexible substrate on which a p-type thermoelectric material is deposited on at least one surface; and
terminals attached to the end surfaces.

15. The thermoelectric device of claim 14, wherein a cross-section of the thermoelectric element along a plane parallel to the end surfaces include
the support structure, and
multiple layers of the flexible substrate and the thermoelectric material.

16. The thermoelectric device of claim 14, wherein the support structure is a hollow tube, and the thermoelectric material is deposited on two opposite surfaces of the flexible substrate.

17. The thermoelectric device of claim 14, further including
a plurality of cover plates, and
electrically conductive members interconnecting the n-type and p-type thermoelectric elements serially.

18. The thermoelectric device of claim 14, wherein the thickness of the flexible substrate is between approximately 20 and 30 microns, and the thickness of the thermoelectric material is between approximately 2 and 10 microns.

19. A method of making a thermoelectric device comprising;
depositing thermoelectric material on a flexible substrate to form a thermoelectric film,
winding the thermoelectric film around a support structure multiple complete turns to form a thermoelectric element;
attaching terminals to parallel end surfaces of the thermoelectric element; and
interconnecting the thermoelectric elements serially with conductive members.

20. The method of claim 19 further including placing the thermoelectric elements in cavities of a plurality of cover plates such that the end surfaces of the thermoelectric elements are substantially parallel to a bottom surface of the cavities.
